(19) United States
(12) Patent Application Publication
(10) Pub. No.: US 2026/0337748 A1
(43) Pub. Date: Oct. 29, 2026

(54) DEPOSITION MASK, METHOD OF MANUFACTURING THE DEPOSITION MASK, AND METHOD OF MANUFACTURING DISPLAY DEVICE USING THE DEPOSITION MASK

(71) Applicant: SAMSUNG DISPLAY CO., LTD., YONGIN-SI (KR)

(72) Inventor: Jin Woo LEE, Yongin-si (KR)

(21) Appl. No.: 19/560,307

(22) Filed: Mar. 9, 2026

(30) Foreign Application Priority Data
Apr. 25, 2025 (KR) 10-2025-0054492

(51) Int. Cl. C23C 14/04; H10K 59/12; H10K 71/16

(52) U.S. Cl. CPC C23C 14/042; H10K 59/1201; H10K 71/166

(57) ABSTRACT

A method for manufacturing a deposition mask may include forming a first mask film and a second mask film on a first surface and a second surface of a mask body, respectively, where the first surface is opposite to the second surface, etching the first mask film to form a mask pattern including deposition holes, forming a protective oxide on the mask pattern, and etching the second mask film and the mask body to form a deposition space. The deposition space is common communication with the deposition holes

### CROSS-REFERENCE TO RELATED APPLICATION

This U.S. non-provisional patent application claims priority under 35 U.S.C. §119 to Korean Patent Application No. 10-2025-0054492 filed on Apr. 25, 2025, in the Korean Intellectual Property Office, the contents of which are incorporated herein by reference in its entirety.

### Technical Field

Embodiments of the present disclosure relate to a deposition mask and, more particularly to, a deposition mask, a method of manufacturing the deposition mask, a method of manufacturing a display device using the deposition mask, and an electronic device including the display device.

### Discussion of the Related Art

In a display device such as an organic light emitting diode (OLED) display, a micro-_OLED display, a liquid crystal display (LCD), a flat panel display, or a foldable panel display, a display substrate including, for example, a thin film transistor (TFT) and various wires may be provided. A display structure including electrodes and a light emitting layer may be formed on the display substrate.

For example, the OLED display device may include a light emitting element having an organic light emitting layer. The organic light emitting layer can be patterned and deposited for each color or each pixel using a deposition mask. As the resolution of the OLED display device increases to high pixel densities, precise fine patterning of the deposition mask may be needed to accurately define the deposition regions for red, green, and blue sub-pixels, or additional sub-pixels such as white or quantum-dot-enhanced emission elements.

### SUMMARY

According to an aspect of the present disclosure, a method for manufacturing a deposition mask may include forming a first mask film and a second mask film on a first surface and a second surface of a mask body, respectively, the first surface is opposite to the second surface, etching the first mask film to form a mask pattern including deposition holes, forming a protective oxide on the mask pattern, and etching the second mask film and the mask body to form a deposition space. The deposition space is in common communication with the deposition holes.

According to some embodiments of the present disclosure, forming the deposition space may include selectively removing a portion of the protective oxide film overlapping the deposition space.

According to some embodiments of the present disclosure, the first mask film may include a silicon nitride, and the protective oxide film may include a silicon oxide.

According to some embodiments of the present disclosure, the protective oxide film may be continuously formed along upper surfaces of the mask pattern, and side surfaces and bottom surfaces of the deposition holes through a deposition process.

According to some embodiments of the present disclosure, the protective oxide film may be formed to partially fill each of the deposition holes through an oxidation process on the mask body or the mask pattern.

According to some embodiments of the present disclosure, the method may further include partially etching an upper portion of the mask body using the mask pattern before forming the protective oxide film to form recesses.

According to some embodiments of the present disclosure, the protective oxide film may completely fill the recesses and be in contact with side surfaces of the mask pattern.

According to some embodiments of the present disclosure, the protective oxide film may include a first portion disposed on a top surface of the mask pattern, and a second portion formed in the deposition holes.

According to some embodiments of the present disclosure, the method may further include forming a guide structure including a magnetic material or a conductive material on the second mask film opposite from the mask body. The deposition space may penetrate the guide structure.

According to some embodiments of the present disclosure, the method may further include forming a seed pattern on the second mask film opposite from the mask body. The guide structure may be formed through a plating process using the seed pattern.

According to some embodiments of the present disclosure, the method may further include forming a buffer oxide film on the first surface or the second surface of the mask body.

According to an aspect of the present disclosure, a deposition mask may include a mask body having a first surface and a second surface opposite from the first surface, and including a deposition space, a mask pattern located on the first surface of the mask body, the mask pattern includes a plurality of deposition holes communicating with the deposition space in a pattern region, and a protective oxide film pattern formed on an outer region of the mask pattern, where the outer region surrounds the inner region.

According to some embodiments of the present disclosure, the deposition mask may further include a second mask film formed on the second surface of the mask body, and the deposition space may penetrate the second mask film and the mask body.

According to some embodiments of the present disclosure, the deposition mask may further include a guide structure spaced apart from the mask body with the second mask film interposed between the guide structure and the mask body. The guide structure may include a magnetic material or a conductive material and surround a bottom portion of the deposition space.

According to some embodiments of the present disclosure, the deposition mask may further include a seed pattern disposed between the guide structure and the second mask film.

According to some embodiments of the present disclosure, the mask pattern and the second mask film may include a silicon nitride.

According to some embodiments of the present disclosure, the deposition space may be configured to receive a deposition material, and the deposition holes may be configured to discharge the deposition material.

According to an aspect of the present disclosure, a method for manufacturing a display device may include preparing a display panel comprising pixel electrodes, and forming light emitting layers by depositing a light emitting material on the pixel electrodes through a deposition mask. The deposition mask may include a mask body having a first surface and a second surface opposite from the first surface, and include a deposition space, a mask pattern located on the first surface of the mask body, the mask pattern includes a plurality of deposition holes communicating with the deposition space in a pattern region, and a protective oxide film pattern formed on an outer region of the mask pattern, where the outer region surrounds the inner region.

According to an aspect of the present disclosure, an electronic device may include a display device including a display panel formed using a deposition mask, a memory having a stored application for operating the electronic device including the display device, and a processor configured to execute the application stored in the memory. The deposition mask may include a mask body having a first surface and a second surface opposite from the first surface, and include a deposition space, a mask pattern located on the first surface of the mask body, the mask pattern includes a plurality of deposition holes communicating with the deposition space in a pattern region, and a protective oxide film pattern formed on an outer region of the mask pattern, where the outer region surrounds the inner region.

According to some embodiments of the present disclosure, the deposition mask may further include a guide structure disposed on the second surface of the mask body. The guide structure may include a magnetic material or a conductive material and surround a bottom portion of the deposition space.

According to some embodiments of the present disclosure, the deposition space is configured to receive a deposition material, and the deposition holes are configured to discharge the deposition material.

### BRIEF DESCRIPTION OF THE DRAWINGS

Embodiments of the present disclosure are apparent from the detailed description with reference to the attached drawings, in which:

FIG. 1 is a schematic plan view illustrating a deposition mask according to embodiments of the present disclosure;

FIG. 2 is a schematic cross-sectional view illustrating the deposition mask shown in FIG. 1;

FIGS. 3, 4, 5, 6, 7, 8, 9, and 10 are schematic cross-sectional views illustrating a method for manufacturing a deposition mask according to embodiments of the present disclosure;

FIG. 11 is a diagram illustrating a method for aligning the deposition mask with a target substrate according to embodiments of the present disclosure;

FIGS. 12 and 13 are schematic cross-sectional views illustrating a method for manufacturing a deposition mask according to embodiments of the present disclosure;

FIGS. 14, 15, 16, 17, and 18 are schematic cross-sectional views illustrating a method for manufacturing a deposition mask according to embodiments of the present disclosure;

FIGS. 19, 20, 21, 22, and 23 are schematic views illustrating a method for manufacturing a display device according to embodiments of the present disclosure;

FIG. 24 is an exploded perspective view showing an electronic device according to embodiments of the present disclosure;

FIG. 25 is a block diagram of an electronic device according to embodiments of the present disclosure; and

FIG. 26 is schematic views of electronic devices according to embodiments of the present disclosure.

### DETAILED DESCRIPTION OF THE EMBODIMENTS

embodiments of the present disclosure are described in detail with reference to the accompanying drawings. This disclosure may be embodied in different forms and should not be construed as limited to the embodiments set forth herein. Rather, these embodiments are provided to describe the technical idea of the present disclosure so that a person skilled in the art can understand and implement the inventive concept.

In the specification, when an element or a layer is described as being "on" another element or layer, this may include a case where the element or layer is directly on the other element or layer, or a case when one or more intervening layers are interposed therebetween. The same reference numerals/symbols may be used to indicate the same components throughout the specification. For example, while each drawing may represent one or more particular embodiments of the present disclosure, drawn to scale, such that the relative lengths, thicknesses, and angles can be inferred therefrom, it is to be understood that the present invention is not necessarily limited to the relative lengths, thicknesses, and angles shown. Changes to these values may be made within the spirit and scope of the present disclosure, for example, to allow for manufacturing limitations and the like

In the specification, the terms “first,” “second,” and the like may be used to describe various elements, but these elements should not be limited thereto. These terms are used to distinguish one element from another element. For example, a first element could be termed as a second element, and similarly, the second element may be referred to as the first element, without departing from the scope of the present disclosure.

The terminology used herein is for describing particular embodiments and is not necessarily intended to be limiting. As used herein, the terms "a", "an," "the," and “at least one” do not denote a limitation of quantity, and are intended to include both the singular and plural, unless the context clearly indicates otherwise. For example, "an element" may be the same as “at least one element," unless the context clearly indicates otherwise. “At least one” is not to be construed as limiting “a” or “an.” The term “or” may be also referred to as “and/or.” As used herein, the term “and/or” includes any and all combinations of one or more of the associated listed items. It will be further understood that the terms “comprises” and/or “comprising,” or “includes” and/or “including” specify the presence of stated features, regions, integers, steps, operations, elements, and/or components, but do not preclude the presence or addition of one or more other features, regions, integers, steps, operations, elements, components, and/or groups thereof.

Spatially relative terms such as “lower” or “bottom” and “upper” or “top,” may be used to describe the relationship of one element to another element as illustrated in the drawings. The spatially relative terms are intended to encompass different orientations of the device in addition to the orientation depicted in the drawings. For example, if the device is rotated or turned over, elements described as being on the “lower” side of other elements would then be oriented on “upper” sides of the other elements. The term “lower,” can therefore, encompasses both an orientation of “lower” and “upper,” based on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Features of each of various embodiments of the disclosure may be partially or entirely combined with each other, and may technically interoperate in different ways, . Each of the embodiments may be implemented independently or in combination with one or more other embodiments.

The term "about" or "approximately" is inclusive of the stated value and refers to values within an acceptable range of deviation as understood by one of ordinary skill in the art, considering the measurement precision and the error or the measurement system. For example, "about" may correspond to a value within one or more standard deviations, or within ± 30%, 20%, 10% or 5% of the stated value.

Embodiments of the present disclosure provide a deposition mask including a mask body having a first surface and a second surface opposite to each other, a deposition space formed in the mask body, and a mask pattern disposed on the first surface of the mask body. The mask pattern includes a pattern region having a plurality of deposition holes connected to the deposition space, and an outer region surrounding the pattern region. A protective oxide film pattern is formed on the outer region of the mask pattern. By reinforcing the outer region of the mask pattern with the protective oxide film pattern, embodiments of the present disclosure improve the strength and rigidity of the deposition mask, and reduce deformation such as warpage or bowing during use, thereby enabling reliable fine patterning and improving alignment accuracy for high-resolution display manufacturing.

Hereinafter, embodiments of the present disclosure are described in detail with reference to the accompanying drawings.

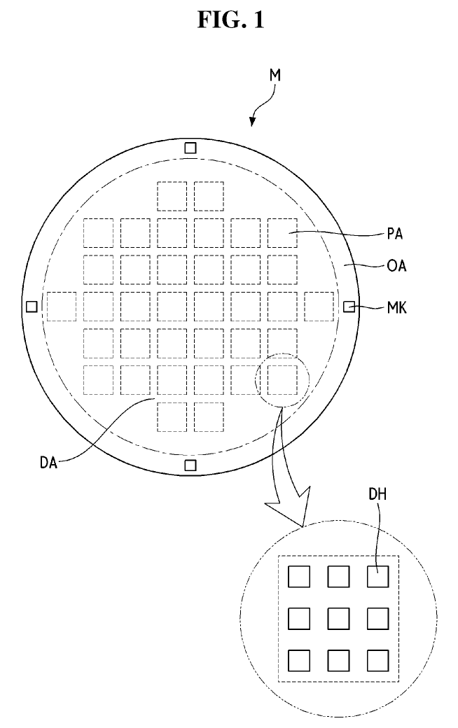

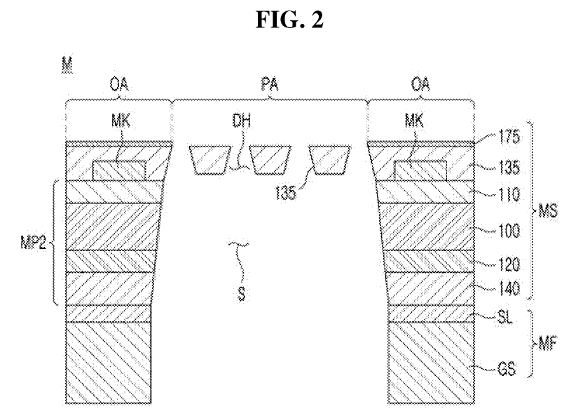

FIG. 1 is a schematic plan view illustrating a deposition mask according to embodiments of the present disclosure. FIG. 2 is a schematic cross-sectional view illustrating the deposition mask shown in FIG. 1.

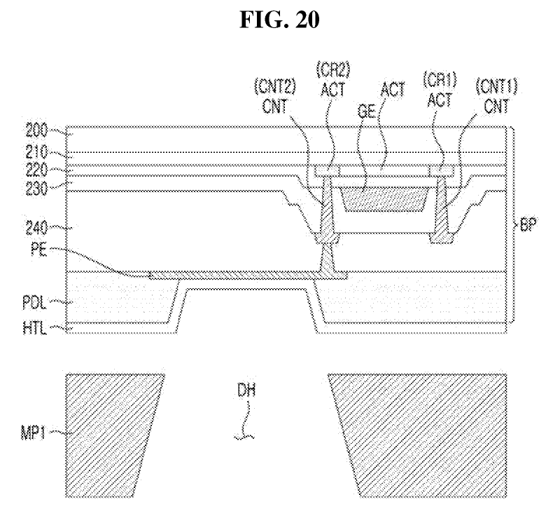

Referring to FIGS. 1 and 2, a deposition mask M may include a mask sheet MS and a mask frame MF. The mask sheet MS may include a pattern region PA, an outer region OA, and a dummy region DA. The mask sheet (MS) may include a second mask portion MP2 and a first mask portion MP1 (see FIGS. 20-22) disposed on the second mask portion MP2. In some cases, the dummy region DA may surround the pattern region PA.

In FIG. 1, the shape of the deposition mask M in a plan view is illustrated as circular, but is not necessarily limited thereto. The shape of the deposition mask M in the plan view may be modified into various forms, such as a quadrilateral or an ellipse.

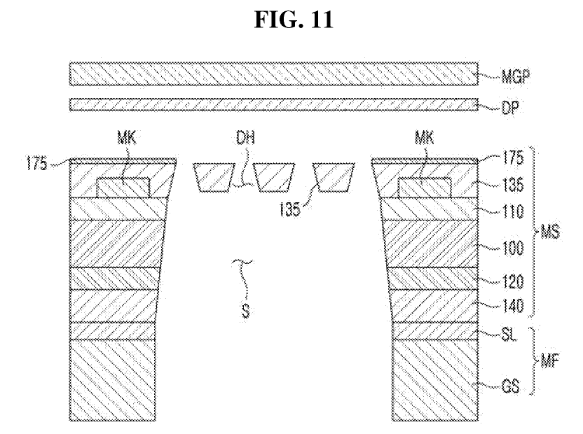

At least one deposition hole DH may be formed in the pattern region PA. A plurality of pattern regions PA may be formed in a single deposition mask M, so that multiple patterns may be simultaneously and repeatedly deposited across different regions or areas on a target substrate DP (see FIG. 11) through a single deposition process. In some cases, the plurality of pattern regions PA may be arranged in a matrix, radial, or staggered configuration to optimize material distribution.

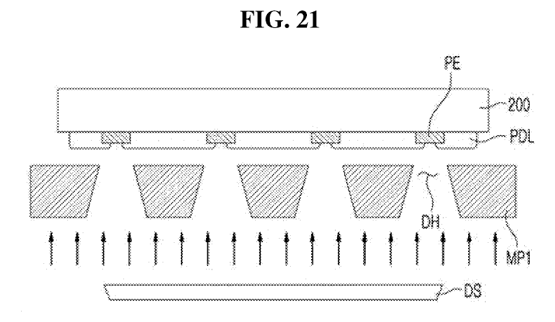

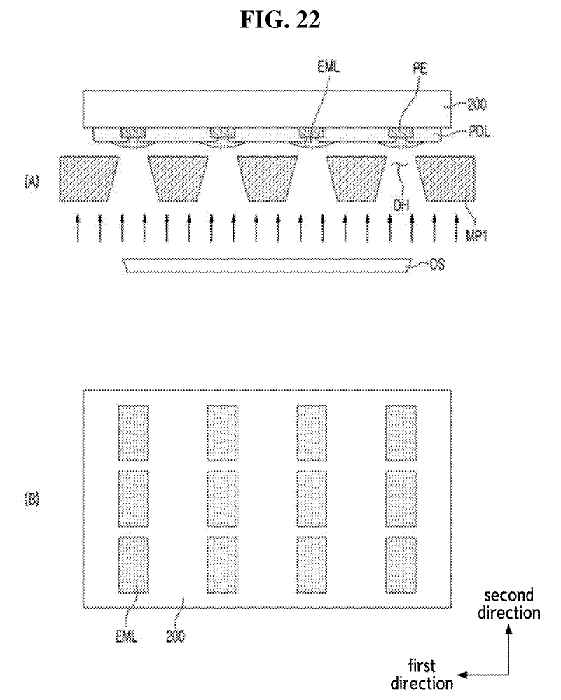

The deposition hole DH may be configured to selectively allow a deposition material to pass through during the deposition process. The deposition material provided from a deposition source DS (see FIGS. 21 and 22) may be guided to pass through the deposition hole DH and be deposited on the target substrate DP. Patterns corresponding to the deposition holes DH of the deposition mask M may be deposited and formed on the target substrate DP. In some embodiments, the deposition holes DH may have tapered or curved sidewalls to improve step coverage, or may include various cross-sectional geometries such as circular, elliptical, or polygonal shapes to adjust deposition uniformity.

The dummy region DA may be configured to partition the respective pattern regions PA. The dummy region DA may form an outer region of the mask sheet MS. The dummy region DA may be formed in a grid shape between the respective pattern regions PA. The shape and area of the dummy region DA may vary based on the number, arrangement interval, or arrangement structure of the pattern regions PA. For example, other configurations such as concentric rings, honeycomb structures, or irregular reinforcement ribs may also be used.

The outer region OA may be a peripheral region of the pattern regions PA. The outer region OA may be an edge region of the deposition mask M.

An alignment key MK may be disposed in the outer region OA. Referring to FIG. 1, four alignment keys MK are illustrated as being arranged at 90° intervals from each other, but the interval and number of the alignment keys MK may be varied. In some embodiments, the alignment keys MK may be disposed asymmetrically to prevent mask misorientation, or may include optical alignment marks detectable by vision systems.

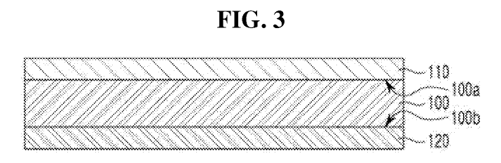

The mask frame MF may be configured to support the mask sheet MS. The mask frame MF may correspond to a remaining region after etching a mask body 100, a first mask film 150, and a second mask film 160 to form the deposition hole DH. The mask frame MF may at least partially overlap the dummy region DA and the outer region OA of the mask sheet MS in a thickness direction of the deposition mask M. In some cases, the mask sheet MS may include a second silicon nitride film 140, second buffer oxide film 120, a mask body 100, a first buffer oxide film 110, a mask pattern 135, and protective oxide film pattern 175 that are sequentially stacked. Further detail on the mask sheet MS is described with reference to FIGS. 3-10.

FIGS. 3-10 are schematic cross-sectional views illustrating a method for manufacturing a deposition mask according to embodiments of the present disclosure.

Referring to FIGS. 3-5, a first mask film 150 and a second mask film 160 may be formed on a first surface 100a and a second surface 100b of a mask body 100, respectively. For example, the first mask film 150 may include a first buffer oxide film 110 and a first silicon nitride film 130. The second mask film 160 may include a second buffer oxide film 120 and a second silicon nitride film 140. In some cases, the first mask film 150 and the second mask film 160 may be formed of different materials.

The mask body 100 may be a substrate that forms a body of the deposition mask M. The mask body 100 may include a material that has stable heat resistance for thermal or vapor deposition and is capable of suppressing thermal deformation. For example, the mask body 100 may include silicon, glass, quartz, or the like. In some embodiments, the mask body 100 may further include composite or multilayer substrates to enhance thermal conductivity or mechanical rigidity.

Hereinafter, a method for manufacturing a deposition mask is described with reference to the deposition mask M in which the mask body 100 is formed of silicon. However, the manufacturing method may be similarly applied to deposition masks made of other materials such as glass or quartz with modifications to process conditions.

The first surface 100a and the second surface 100b of the mask body 100 may be opposite to each other and may correspond to a top surface and a bottom surface of the mask body 100, respectively. According to some embodiments, the second surface 100b may be a deposition material injection surface through which a deposition material is introduced into the deposition mask M. The first surface 100a may be a deposition material supply surface through which the deposition material passes through the deposition mask M and is supplied to a target object.

The first mask film 150 may include a first buffer oxide film 110 formed on the first surface 100a and a first silicon nitride film 130 formed on the first buffer oxide film 110. The second mask film 160 may include a second buffer oxide film 120 formed on the second surface 100b and a second silicon nitride film 140 formed on the second buffer oxide film 120.

The first mask film 150 formed on the first surface 100a of the mask body 100 may include the first silicon nitride film 130. The first mask film 150 may further include the first buffer oxide film 110 disposed between the first silicon nitride film 130 and the mask body 100. Alternatively, the first mask film 150 may include an additional or a different material, for example, alumina (Al₂O₃) or silicon oxycarbide (SiCₓO_{y}).

The second mask film 160 formed on the second surface 100b of the mask body 100 may include the second silicon nitride film 140. The second mask film 160 may further include the second buffer oxide film 120 disposed between the second silicon nitride film 140 and the mask body 100. Alternatively, the second mask film 160 may include an additional or a different material, for example, alumina (Al₂O₃) or silicon oxycarbide (SiCₓO_{y}). In some embodiments, the material composition of the first mask film 150 and the second mask film 160 may be different.

For example, the first buffer oxide film 110 and the second buffer oxide film 120 may be formed by oxidizing the mask body 100. Alternatively, the first buffer oxide film 110 and the second buffer oxide film 120 may be formed on the mask body 100 by a plasma-enhanced chemical vapor deposition (PECVD) process.

For example, the first buffer oxide film 110 and the second buffer oxide film 120 may have different thicknesses.

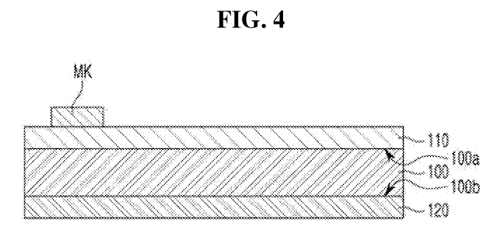

Referring to FIG. 4, the alignment key MK may be disposed on at least one side of the first buffer oxide film 110. In some embodiments, the alignment key MK may extend partially onto the mask body 100 to increase adhesion strength and precision alignment.

The alignment key MK is used for aligning the deposition mask M with the target substrate DP and may be positioned in the outer region OA of the mask sheet MS. For example, the alignment key MK may include a metal material such as aluminum.

The alignment key MK may be formed on one side of the mask body 100, or on opposite sides thereof. In some embodiments, alignment keys MK may also be staggered or asymmetrically positioned to prevent mask inversion during the manufacturing process.

The alignment key MK may be formed on the first buffer oxide film 110 by patterning an alignment layer. For example, the alignment key MK may be formed by forming an alignment layer on the first buffer oxide film 110, performing an exposure process using a photomask and development process, and then etching the alignment layer. In some embodiments, the alignment key MK may be formed by additive processes such as screen printing or inkjet deposition of a metal material.

After manufacturing the deposition mask M, the alignment key MK may serve to align the deposition mask M with the target substrate DP when supplying the deposition material to the target substrate DP through the deposition mask M.

According to some embodiments, a plurality of alignment keys MK may be formed. A predetermined number of alignment keys MK may be formed to align the deposition mask M with the target substrate DP (see FIG. 11). For example, when the size of the deposition mask M is large, or when precise alignment between the deposition mask M and the target substrate DP is desired, the number of alignment keys MK may be increased.

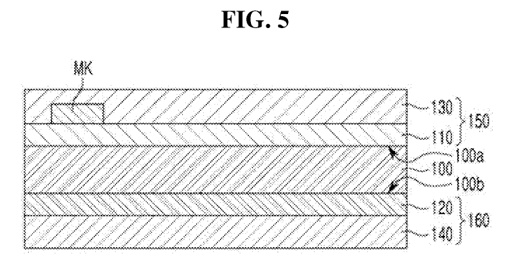

Referring to FIG. 5, the first silicon nitride film 130 and the second silicon nitride film 140 may be formed on the first buffer oxide film 110 and the second buffer oxide film 120, respectively. For example, the first silicon nitride film 130 and the second silicon nitride film 140 may be formed by a low pressure chemical vapor deposition (LPCVD) process.

In FIG. 5, the first silicon nitride film 130 and the second silicon nitride film 140 are illustrated to be thicker than the first buffer oxide film 110 and the second buffer oxide film 120, respectively. In some cases, the thickness ratios may vary based on design requirements. For example, the first silicon nitride film 130 and the second silicon nitride film 140 may have different thicknesses.

For example, the thickness of the first silicon nitride film 130 may be less than that of the first buffer oxide film 110, or the thickness of the first silicon nitride film 130 may be equal to the thickness of the first buffer oxide film 110. In some embodiments, the thickness of the first silicon nitride film 130 and second silicon nitride film 140 may be graded across the mask to accommodate thermal gradients during deposition, or may include multi-layer stacks of nitride and oxide films.

However, the first mask film 150 and the second mask film 160 are not necessarily limited to the above-described embodiment, and the deposition mask M may include one of the first buffer oxide film 110 and the second buffer oxide film 120, and the first silicon nitride film 130 and the second silicon nitride film 140. Alternatively, the first mask film 150 and the second mask film 160 may include other materials, such as alumina (Al₂O₃) or silicon oxycarbide (SiCₓO_{y}).

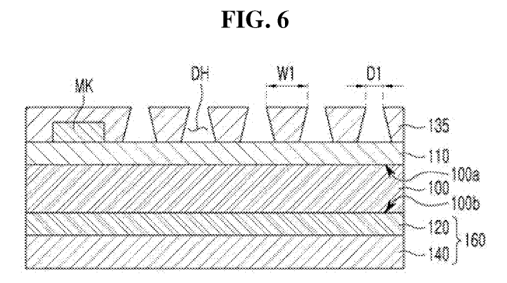

Referring to FIG. 6, a mask pattern 135 including the deposition holes DH may be formed by partially etching the first silicon nitride film 130 of the first mask film 150. In some embodiments, the mask pattern 135 may be formed by dry etching, wet etching, or a combination thereof.

The mask pattern 135 may include the pattern region PA including the plurality of deposition holes DH and the outer region OA surrounding the pattern region.

Widths W1 and separation distances D1 of the respective mask patterns 135 may differ from each other. For example, the width W1 of one mask pattern 135 may differ from the width W1 of an adjacent mask pattern 135. In addition, the separation distance D1 between adjacent mask patterns 135 may differ from the separation distance D1 between another mask patterns 135. In some cases, the Widths W1 may be greater than the separation distances D1.

The width W1 of the mask pattern 135 may be a width based on the top surface of the mask pattern 135. The separation distance D1 of the mask pattern 135 may be a distance based on the top surfaces of adjacent mask patterns 135. In some embodiments, the width W1 and separation distance D1 may be defined at the mid-point or bottom of the mask pattern sidewalls, particularly in the case of tapered or curved etch profiles.

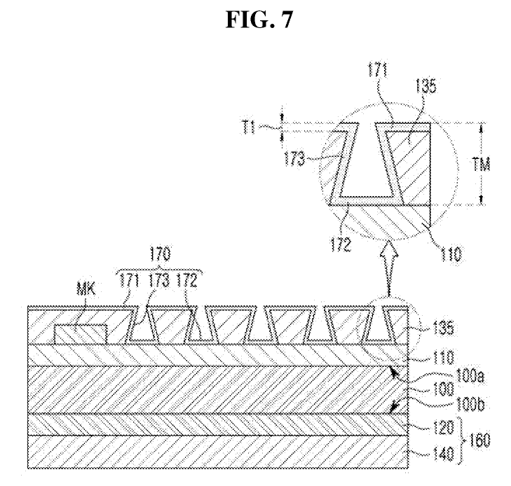

Referring to FIG. 7, a protective oxide film 170 may be formed on the mask pattern 135. In some embodiments, the protective oxide film 170 may extend partially into the deposition hole DH or onto adjacent surfaces (or an upper surface) of the first buffer oxide film 110.

The protective oxide film 170 may include silicon oxide (SiOₓ). The protective oxide film 170 may be in contact with the mask pattern 135 in the deposition hole DH. The protective oxide film 170 may be continuously formed along the surface of the mask pattern 135 and the bottom surfaces of the deposition holes DH through a deposition process. In some embodiments, the protective oxide film 170 may include other oxides such as aluminum oxide (Al₂O₃), hafnium oxide (HfO₂), or multilayer oxide stacks.

The protective oxide film 170 may include a first portion 171 formed on the top surface of the mask pattern 135 and a second portion 172 formed on the bottom surface of the deposition hole DH. For example, the second portion 172 may be formed on the upper surface of the first buffer oxide film 110. The protective oxide film 170 may further include a third portion 173 formed on the side surface of the mask pattern 135 and connecting the first portion 171 to the second portion 172. In some embodiments, the third portion 173 may be formed integrally with the first portion 171 and the second portion 172.

The protective oxide film 170 may be formed on the mask pattern 135 to enhance the rigidity of the deposition mask M. In some cases, the protective oxide film 170 may function as an etch barrier or thermal barrier layer.

For example, during an etching process of the mask body 100 and the second mask film 160, the protective oxide film 170 may increase the rigidity of the mask pattern 135 by increasing the thickness of the mask pattern 135.

The protective oxide film 170 may be formed using the same material and the same method as the first buffer oxide film 110. For example, the protective oxide film 170 may be formed by thermally oxidizing silicon, plasma-enhanced chemical vapor deposition (PECVD), or atomic layer deposition (ALD).

The deposition mask M may be manufactured by etching the second mask film 160 and the mask body 100 to form a deposition space S that is in common communication with the deposition holes DH. Based on an etch selectivity of the mask body 100, the protective oxide film 170 may be formed with a corresponding thickness.

When the protective oxide film 170 is formed by a deposition method, a thickness T1 of the protective oxide film 170 may be in a range from about 0.2 µm to about 1.0 µm. The thickness T1 of the protective oxide film 170 may be measured from a height direction of the deposition mask M. For example, the height direction may be perpendicular to an upper surface of the protective oxide film 170. The thickness of the first portion 171 may be measured from a distance from the outer surface of the mask pattern 135 to the outer surface of the first portion 171. The thickness of the second portion 172 may be a thickness of the second portion 172 located in the deposition hole DH, which is formed by etching the first mask film 150.

For example, the thicknesses of the second portion 172 and the first portion 171 may be the same or different from each other. In some embodiments, the second portion 172 may be thicker to reinforce the bottom of the deposition hole DH, while the first portion 171 may be thinner to minimize top-surface obstruction.

For example, the first portion 171 and the second portion 172 may be integrally formed. Alternatively, the first portion 171 and the second portion 172 may be separately deposited and subsequently annealed.

When the thickness of the protective oxide film 170 is less than 0.2 µm, the rigidity reinforcement effect of the deposition mask M may be insignificant.

When the thickness of the protective oxide film 170 is greater than 1.0 µm, the thickness of the deposition mask M may become excessively large. If the thickness of the deposition mask M becomes too large, problems such as shadowing may occur during subsequent deposition of the deposition material onto the target substrate.

A height TM of the deposition mask M may be a distance measured from the bottom surface of the second portion 172 to the top surface of the first portion 171. For example, the height TM of the deposition mask M may be a distance measured from the upper surface of first buffer oxide film 110 to the upper surface of the first portion 171. The height TM of the deposition mask M may be about 4 μm to 5 μm.

When the height TM of the deposition mask M is less than 4 µm, the strength of the deposition mask M may be low, so that defects such as the mask pattern 135 breaking or being damaged may occur during a subsequent etching process of the second mask film 160.

When the height TM of the deposition mask M is greater than 5 µm, the deposition mask M may become thick, causing a shadow, so that the deposition of the deposition material on the target substrate DP might not be precisely formed.

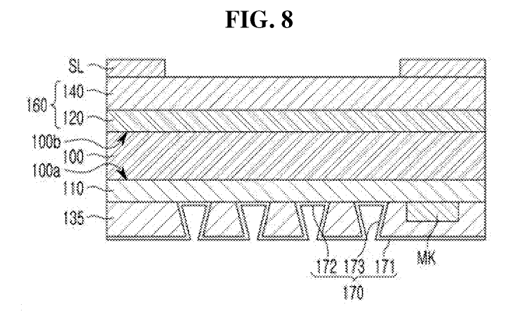

Referring to FIG. 8, a seed pattern (or a seed layer) SL may be formed on the second mask film 160. The seed pattern SL may be a base layer for forming a guide structure GS. The seed pattern SL may include a metal material. The seed pattern SL may be formed by a physical vapor deposition (PVD) method, a chemical vapor deposition (CVD) method, or a sputtering method.

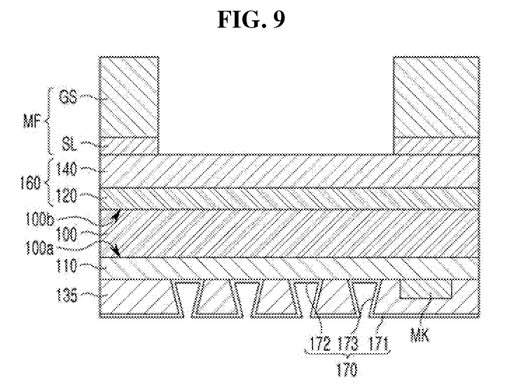

Referring to FIG. 9, the guide structure GS may be formed on the seed pattern SL. For example, the guide structure GS may be formed by electroplating or sputtering.

The guide structure GS may include a magnetic material or a conductive material. For example, the guide structure GS may include copper (Cu), nickel (Ni), cobalt (Co), or other metal elements or compounds. Alternatively, for example, the guide structure GS may include a composite of materials having magnetic properties or a polymer containing a magnetic material.

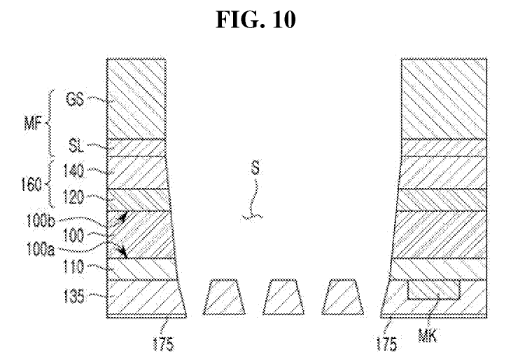

Referring to FIG. 10, the deposition space S that is in common communication with the deposition holes DH may be formed by etching portions of the mask body 100, the second mask film 160, and the first mask film 150 (e.g., including the first buffer oxide film 110 and the mask pattern 135). In the step of forming the deposition space S, a portion of the protective oxide film 170 overlapping the deposition space S may be selectively removed. Accordingly, the protective oxide film pattern 175 may be formed.

The deposition space S may be formed by performing wet etching. In some embodiments, dry etching, plasma etching, or a hybrid wet/dry etching may be employed to form the deposition space S.

The deposition space S may penetrate the second mask film 160, the mask body 100, and the first buffer oxide film 110. The deposition space S may be in common communication with the deposition holes DH. In some cases, for example, the deposition space S may open into the deposition holes DH. In some cases, the deposition space S may be adjacent to the deposition holes DH. In some cases, the deposition space S may be connected to the deposition holes DH.

For example, a portion of the protective oxide film 170 may also be etched, so that the second portion 172 and the third portion 173 are removed, and the first portion 171 in the pattern region PA may also be removed. The first portion 171 of the outer region OA may remain. A protective oxide film pattern 175 may be formed in the outer region OA. Through this process, the deposition mask M illustrated in FIG. 2 may be formed. In some embodiments, the protective oxide film pattern 175 may be patterned into segmented island shapes to form the deposition mask M.

The deposition space S may be provided as an introduction region for a deposition material, and the deposition holes DH may be provided as a discharge region for the deposition material. In some embodiments, flow-directing features may be incorporated within the deposition space S to improve uniformity of material distribution toward the deposition holes DH. For example, the deposition material may enter into the deposition space S and exit from deposition holes DH.

FIG. 11 is a diagram illustrating a method for aligning the deposition mask M with a target substrate according to embodiments of the present disclosure.

A process of depositing the deposition material on the target substrate DP may be performed in a vacuum chamber. The deposition mask M may be arranged below the target substrate DP on which deposition is to be performed, and a magnet plate MGP may be arranged above the target substrate DP. When the magnet plate MGP is lowered and the deposition mask M is raised with the target substrate DP interposed between the magnet plate MGP and the deposition mask M, sagging or bowing of the deposition mask M may be prevented by magnetic force between the magnet plate MGP and the guide structure GS of the deposition mask M. The magnetic force applied to the deposition mask M by the magnet plate MGP may be an attractive force.

In some cases, when a member, such as the guide structure GS, having magnetic properties not formed in the deposition mask M, a separate supporter may be needed to fix the deposition mask M to the magnet plate MGP. When the magnet plate MGP and the deposition mask M are connected using a separate supporter, the deposition mask M may warp or bow. However, as in the deposition mask M, when a magnetic guide structure GS is formed in the deposition mask M, the deformation of the deposition mask M may be reduced by the magnetic force between the deposition mask M and the magnet plate MGP. Therefore, deposition may be precisely performed on the target substrate DP.

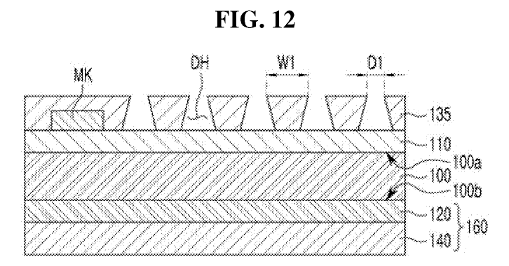

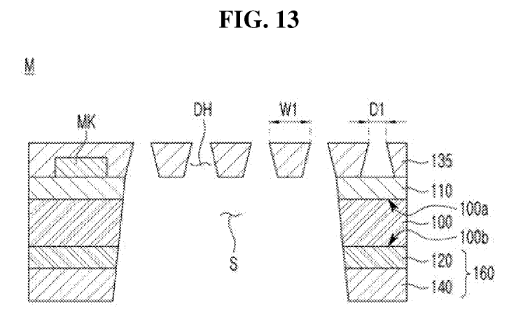

FIGS. 12 and 13 are schematic cross-sectional views illustrating a method for manufacturing a deposition mask according to embodiments of the present disclosure.

Referring to FIG. 12, as described with reference to FIGS. 3-6, the first mask film 150 may be formed on the first surface 100a of the mask body 100, and the second mask film 160 may be formed on the second surface 100b opposite to the first surface 100a. When forming the first mask film 150, the alignment key MK may be formed on the first buffer oxide film 110. The first silicon nitride film 130 may be formed on the first buffer oxide film 110 and the alignment key MK, and the first silicon nitride film 130 may be etched to form the mask pattern 135 including the deposition hole DH. In some cases, the deposition hole DH may include tapered, stepped, or curved profiles based on the etching parameters and target material flow characteristics.

Referring to FIG. 13, the deposition mask M including the mask sheet MS may be manufactured by etching the second surface 100b of the mask body 100 and the second mask film 160 to form the deposition space S in communication with the deposition hole DH. In some embodiments, the etching of the second surface 100b and the second mask film 160 may be performed in multiple steps to remove different layers. In some cases, the second surface 100b and the second mask film 160 may be etched using a single process.

As the mask pattern 135 of the mask sheet MS is scaled down, the width W1 of the mask pattern 135 or the separation distance D1 between adjacent patterns may be reduced. Accordingly, when forming the deposition space S by etching the second surface 100b of the mask body 100 and the second mask film 160, sufficient rigidity is required to prevent breakage of the mask pattern 135. If the rigidity of the mask pattern 135 is not sufficiently ensured, there may be limitations in scaling down the mask pattern 135.

However, according to the above-described embodiments, before etching the second surface 100b of the mask body 100 and the second mask film 160, the protective oxide film 170 may be formed on the mask pattern 135 to increase the thickness of the mask pattern 135, thereby enhancing the strength of the mask sheet MS. Accordingly, fine patterns may be easily formed.

In addition, when depositing the deposition material on the target substrate DP using the deposition mask M, a gap may be formed between the deposition mask M and the target substrate due to deformation such as warpage or bowing of the mask sheet MS.

According to the above-described comparative example, a separate supporter may be needed to connect the deposition mask M to the target substrate and to fix the deposition mask M and the target substrate such that a gap is not formed between the deposition mask M and the target substrate. For example, a supporter having the same pattern as the deposition mask M may be prepared. In addition, when a separate supporter is used to connect the deposition mask M to the magnet plate MGP with the target substrate DP interposed between the deposition mask M and the magnet plate MGP, a gap may occur between the supporter and the deposition mask M, or warpage or bowing of the deposition mask M may occur compared to a case where the guide structure is integrally formed on the deposition mask M.

However, according to the above-described embodiments, when the mask frame MF including the guide structure GS is formed, the separate supporter may be omitted when connecting the mask sheet MS to the magnet plate MGP. In addition, since the guide structure GS is integrally formed with the mask sheet MS, problems such as bowing or warpage of the mask sheet MS may be reduced.

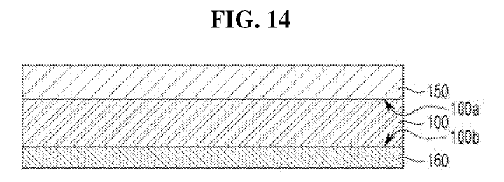

FIGS. 14-18 are schematic cross-sectional views illustrating a method for manufacturing a deposition mask according to embodiments of the present disclosure. Detailed descriptions of processes and materials that are substantially the same as or similar to those described with reference to FIGS. 3-6 might not be described.

Although the alignment key MK is not shown in FIGS. 14-18, the alignment key MK may be formed with reference to FIG. 4.

Referring to FIG. 14, the first mask film 150 and the second mask film 160 may be formed on the first surface 100a and the second surface 100b of the mask body 100, respectively. In some embodiments, the first mask film 150 and the second mask film 160 may be deposited sequentially in a single chamber to reduce contamination, or may be deposited in separate chambers to allow use of different materials for each surface.

The first mask film 150 and the second mask film 160 may include silicon nitride.

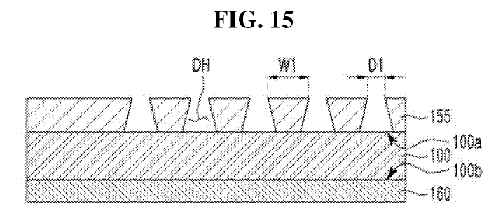

Referring to FIG. 15, the first mask film 150 may be partially etched to form a mask pattern 155. Accordingly, the mask pattern 155 including the deposition hole DH may be formed from the first mask film 150. In some embodiments, the mask pattern 155 may be formed using dry etching, wet etching, or a combination thereof. In some cases, a multilayer etch-stop structure may be employed to improve process control and minimize over-etching into adjacent regions. The shape of the deposition hole DH may include vertical, tapered, or curved profiles tailored for controlling deposition material distribution.

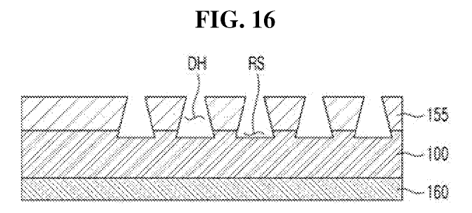

Referring to FIG. 16, the upper portion of the mask body 100 may be partially etched using the mask pattern 155 to form a recess RS. The recess RS may have a concave shape indented from the first surface 100a of the mask body 100. The recess RS may communicate with the deposition hole DH. In some embodiments, the recess RS may have a tapered, stepped, or curved cross-sectional profile to improve the flow of deposition material. Alternatively, the recess RS may be extended laterally to create a widened cavity with respect to the deposition hole DH.

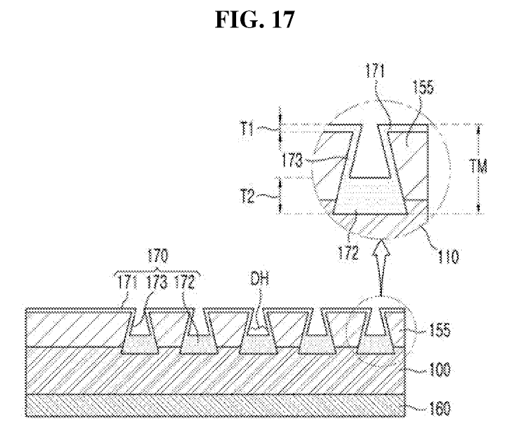

Referring to FIG. 17, the protective oxide film 170 may be formed in the deposition hole DH through an oxidation process on the mask body 100 and/or the mask pattern 155. When forming the protective oxide film 170, the recess RS may be completely filled to form the second portion 172, the deposition hole DH may be partially filled, and the third portion 173 may be formed on the side surface of the mask pattern 155. In addition, in the step of forming the protective oxide film 170, the first portion 171 may be formed on the top surface of the mask pattern 155.

When the protective oxide film 170 is formed by an oxidation method, the thicknesses of the first portion 171 and the second portion 172 may be different from each other. For example, the thickness of the second portion 172 may be greater than the thickness of the first portion 171.

A second thickness T2 of the second portion 172 may be about 6.5 to 7.5 times greater than a first thickness T1 of the first portion 171. The second thickness T2 of the second portion 172 may be about 340 nm to 360 nm, and the first thickness T1 of the first portion 171 may be about 49 nm to 51 nm. For example, the second thickness T2 of the second portion 172 may be about 350 nm, and the first thickness T1 of the first portion 171 may be about 50 nm. In some embodiments, the relative ratio between the first thickness T1 and the second thickness T2 may be adjusted outside of the above-described range based on the properties of the protective oxide film 170.

When the protective oxide film 170 is formed by the oxidation method, the height TM of the deposition mask M may also be about 4 µm to about 5 µm, as in the case of forming the protective oxide film 170 by the above-described deposition method. Referring to FIG. 17, the height TM of the deposition mask M may be a distance from the bottom surface of the second portion 172 to the top surface of the first portion 171. In some embodiments, the height TM may vary across the deposition mask M.

Subsequently, as described with reference to FIGS. 8 and 9, the seed pattern SL and the guide structure GS may be formed under the second mask film 160. In certain embodiments, additional adhesion layers or diffusion barrier layers may be interposed between the second mask film 160 and the seed pattern SL.

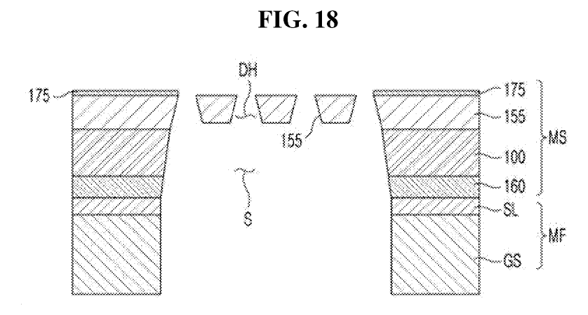

Then, referring to FIG. 18, the mask body 100 and the second mask film 160 may be etched to form the deposition space S.

As described above, the deposition space S may communicate with the deposition holes DH. The deposition space S may be provided as an introduction region for the deposition material, and the deposition holes DH may be provided as a discharge region for the deposition material. In some embodiments, the deposition space S may further include flow-guiding structures or partition walls to equalize material distribution.

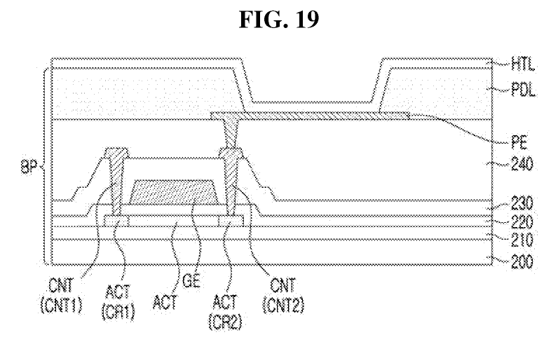

FIGS. 19-23 are schematic views illustrating a method of manufacturing a display device according to embodiments of the present disclosure.

A base substrate 200 may be provided as a backplane substrate of the display device. A glass substrate or a plastic substrate may be used as the base substrate 200. In some embodiments, the base substrate 200 may include a polymer material having transparency and a certain degree of flexibility. For example, the base substrate 200 may be employed in a transparent flexible display device. In some embodiments, the base substrate 200 may include a composite of glass and polymer layers.

For example, the base substrate 200 may include a polymer material such as polyimide, polysiloxane, epoxy resin, acrylic resin, or polyester. In one embodiment, the base substrate 200 may include polyimide. Alternatively, the base substrate 200 may include transparent conductive polymers or hybrid organic-inorganic composites.

A buffer layer 210 may be formed on the top surface of the base substrate 200. The buffer layer 210 may block moisture permeating through the base substrate 200 and may block impurity diffusion between the base substrate 200 and a structure formed on the base substrate 200. The buffer layer 210 may cover the entire top surface of the base substrate 200. In some embodiments, the buffer layer 210 may further act as a planarization layer to provide a uniform surface.

The buffer layer 210 may include, for example, an inorganic insulating material such as silicon oxide, silicon nitride, or silicon oxynitride. These materials may be used alone or in combination with two or more. In some embodiments, the buffer layer 210 may have a stacked structure including a silicon oxide film and a silicon nitride film. The buffer layer 210 may be formed through a deposition process such as a chemical vapor deposition (CVD) process, a sputtering process, or an atomic layer deposition (ALD) process.

In some embodiments, the buffer layer 210 may also include an organic layer and may have a multilayer structure of an organic layer and an inorganic layer.

A semiconductor layer may be formed on the top surface of the buffer layer 210 through a deposition process such as a sputtering process. The semiconductor layer may be patterned to be repeatedly and regularly arranged for each pixel through a photolithography process, thereby forming an active layer ACT.

In some embodiments, the semiconductor layer may include a silicon compound such as polysilicon or amorphous silicon. In some embodiments, the semiconductor layer may be formed to include an oxide semiconductor such as indium gallium zinc oxide (IGZO), zinc tin oxide (ZTO), or indium tin zinc oxide (ITZO).

A gate insulating layer 220 that covers the active layer ACT may be formed on the buffer layer 210. A gate electrode GE may be formed on the gate insulating layer 220. The gate insulating layer 220 may further reduce leakage current.

The gate insulating layer 220 may be formed using the above-described inorganic insulating material and deposition process.

After forming a first conductive layer on the top surface of the gate insulating layer 220, the first conductive layer may be partially removed through a photolithography process to form the gate electrode GE.

For example, the first conductive layer may include a metal such as silver (Ag), magnesium (Mg), aluminum (Al), tungsten (W), copper (Cu), nickel (Ni), chromium (Cr), molybdenum (Mo), titanium (Ti), platinum (Pt), tantalum (Ta), neodymium (Nd), or scandium (Sc), an alloy thereof, or a nitride thereof. In some embodiments, the first conductive layer may be formed in a multilayer structure (e.g., a Ti layer, an Al layer, and a Ti layer).

Subsequently, a p-type dopant or an n-type dopant may be implanted into the active layer ACT through an ion implantation process using the gate electrode GE as an ion implantation mask. Accordingly, a first contact region CR1 and a second contact region CR2 may be formed on one side portion and the other side portion of the active layer ACT, respectively. The first contact region CR1 and the second contact region CR2 may correspond to a source region and a drain region, respectively.

A portion of the active layer ACT overlapping the gate electrode GE in a vertical direction, and the active layer ACT may be disposed between the first contact region CR1 and the second contact region CR2 as a channel region.

A transistor may be defined by the active layer ACT including the channel region, the first contact region CR1, and the second contact region CR2, the gate insulating layer 220, and the gate electrode GE. The transistor may be provided as a thin film transistor (TFT) of the display device and may be provided as a pixel driving transistor or a switching transistor.

An interlayer insulating layer 230 that covers the gate insulating layer 220 and the gate electrode GE may be formed above the active layer ACT. A contact electrode CNT that is in contact with or electrically connected to the active layer ACT may be formed on the interlayer insulating layer 230. For example, the contact electrode CNT may penetrate interlayer insulating layer 230.

The interlayer insulating layer 230 may be formed through the above-described deposition process to include an inorganic insulating material such as silicon oxide, silicon nitride, or silicon oxynitride. The interlayer insulating layer 230 may be formed in a single-layer structure or a multilayer structure including different materials. In some embodiments, the interlayer insulating layer 230 may further include organic insulating films.

In some embodiments, the gate insulating layer 220 may also be formed in a pattern that covers the channel region through an etching process using the gate electrode GE as an etching mask. When the active layer ACT includes an oxide semiconductor, hydrogen (H) contained in the interlayer insulating layer 230 may be diffused or migrated into the active layer ACT during the formation of the interlayer insulating layer 230. Accordingly, the carrier concentration is increased by the hydrogen, and thus the contact regions CR1 and CR2 may be formed on the side portions of the active layer ACT.

The contact electrode CNT may penetrate the interlayer insulating layer 230 and be in contact with or connected to the active layer ACT. The contact electrode CNT may also penetrate the gate insulating layer 220.

The contact electrode CNT may include a first contact electrode CNT1 that is connected to or in contact with the first contact region CR1 of the active layer ACT, and a second contact electrode CNT2 that is connected to or in contact with the second contact region CR2 of the active layer ACT. The first contact electrode CNT1 and the second contact electrode CNT2 may be provided as a source electrode and a drain electrode, respectively. In some embodiments, asymmetric source/drain electrode structures may be employed.

Contact holes may be formed by partially etching the interlayer insulating layer 230. For example, contact holes that respectively expose the first contact region CR1 and the second contact region CR2 may be formed. After forming a second conductive layer on the interlayer insulating layer 230 to sufficiently fill the contact holes, the second conductive layer may be partially etched to form the first contact electrode CNT1 and the second contact electrode CNT2.

The second conductive layer may include a metal or an alloy that is substantially the same as or similar to the first conductive layer and may be formed through the above-described deposition process such as a sputtering, chemical vapor deposition (CVD), or atomic layer deposition (ALD). In some cases, the second conductive layer may also include transparent conductive oxides such as indium tin oxide (ITO) or indium zinc oxide (IZO).

A planarization layer 240 that covers the contact electrode CNT may be formed on the interlayer insulating layer 230. The planarization layer 240 may accommodate a via portion that electrically connects a pixel electrode PE to the second contact electrode CNT2. In some cases, the planarization layer 240 may cover the interlayer insulating layer 230, the first contact electrode CNT1, and the second contact electrode CNT2.

In some embodiments, the planarization layer 240 may include an organic material such as polyimide, epoxy resin, acrylic resin, polyester, siloxane-based resin, or benzocyclobutene (BCB). For example, the planarization layer 240 may be formed through a coating process such as a spin coating process.

The pixel electrode PE may be formed for each pixel and may be electrically connected to the transistor. The pixel electrode PE may be formed on the planarization layer 240 and may be electrically connected to, for example, the second contact electrode CNT2. For example, a contact hole may be formed through a portion of the planarization layer 240 to expose a portion of an upper surface of the second contact electrode CNT2. Then pixel electrode PE may be formed within the contact hole. In some embodiments, the pixel electrode PE may be patterned into sub-pixel electrodes corresponding to red, green, and blue emission regions in a full-color display.

For example, the planarization layer 240 may be partially etched to form a via hole that exposes the top surface of the second contact electrode CNT2. After forming a conductive layer including a metal material or a transparent conductive oxide on the top surface of the planarization layer 240 to sufficiently fill the via hole, the conductive layer may be etched to form the pixel electrode PE. The pixel electrode PE may include the via portion that fills the via hole.

The pixel electrode PE may be provided as an anode and may include a high work function conductive material that promotes hole injection. The pixel electrode PE may be provided as a transmissive electrode. The pixel electrode PE may include a transparent conductive oxide such as indium tin oxide (ITO), indium zinc oxide (IZO), zinc oxide (ZnO), or indium tin zinc oxide (ITZO).

The pixel electrode PE may also be provided as a semi-transmissive electrode or a reflective electrode. The pixel electrode PE may include a metal including silver (Ag), magnesium (Mg), copper (Cu), aluminum (Al), platinum (Pt), palladium (Pd), gold (Au), nickel (Ni), neodymium (Nd), iridium (Ir), chromium (Cr), lithium (Li), calcium (Ca), lithium fluoride (LiF), molybdenum (Mo), titanium (Ti), tungsten (W), indium (In), tin (Sn), and zinc (Zn), or an alloy of two or more of these materials. In some embodiments, multilayer stacks of metal/oxide or metal/nitride may be employed.

The pixel electrode PE may have a single-layer structure or a multilayer structure. For example, the pixel electrode PE may have a three-layer structure of ITO/Ag/ITO.

A pixel defining film PDL that exposes the top surface of the pixel electrode PE may be formed on the planarization layer 240. The pixel defining film PDL may be formed to at least partially expose the top surface of the pixel electrode PE, thereby defining the pixels. The pixel defining film PDL may cover a peripheral portion of the pixel electrode PE. For example, the pixel defining film PDL may cover ends of upper surface and side surfaces of the pixel electrode PE.

For example, a pixel area or an emission area may be defined by the sidewall of the pixel defining film PDL. The shape of the sidewall may be vertical, tapered, or curved to optimize coating or deposition uniformity of organic emissive layers.

The pixel defining film PDL may include an organic material such as polysiloxane resin, polyimide resin, or acrylic resin. The pixel defining film PDL may also include a colorant such as black pigment or dye dispersed in the resin material.

In some embodiments, a hole transport layer HTL may be formed on a backplane structure BP manufactured as described above. The hole transport layer HTL may be formed as a common layer continuously formed across a plurality of pixels. For example, the hole transport layer HTL may cover an upper surface and side surfaces of the pixel defining film PDL and the exposed upper surface of the pixel electrode PE.

For example, the hole transport layer HTL may include a hole transport material such as 4,4',4"-[tris(3-methylphenyl)phenylamino]triphenylamine (m-MTDATA), 4,4',4"-Tris(N,N-diphenylamino)triphenylamine (TDATA), 4,4',4"-tris[N(2-naphthyl)-N-phenylamino]-triphenylamine (2-TNATA), N,N'-di(1-naphthyl)-N,N'-diphenylbenzidine (NPB), N,N'-bis(3-methylphenyl)-N,N'-diphenyl-[1,1'-biphenyl]-4,4'-diamine (TPD), 4,4',4"-tris(N-carbazolyl)triphenylamine (TCTA), or poly(3,4-ethylenedioxythiophene)/poly(4-styrenesulfonate) (PEDOT/PSS).

The hole transport layer HTL may be formed through a process such as thermal deposition, vapor deposition, vacuum deposition, spin coating, inkjet printing, laser printing, casting, or laser thermal transfer.

In one embodiment, a hole injection layer may further be formed between the pixel electrode PE and the hole transport layer HTL.

Referring to FIG. 20, the backplane structure BP may be disposed above the deposition mask M according to the above-described embodiments.

According to embodiments, the backplane structure BP may be aligned such that the pixel electrode PE of the backplane structure BP faces the deposition hole DH of the deposition mask M. The backplane structure BP and the deposition mask M may be aligned with each other such that the deposition hole DH faces the pixel electrode PE.

As described above, the hole transport layer HTL may be formed on the pixel electrode PE. Accordingly, the backplane structure BP and the deposition mask M may be aligned with each other such that the pixel electrode PE faces the deposition hole DH of the deposition mask M with the hole transport layer HTL interposed between the pixel electrode PE and the deposition hole DH. In some embodiments, alignment may be dynamically adjusted during deposition to compensate for thermal expansion or mechanical offsets.

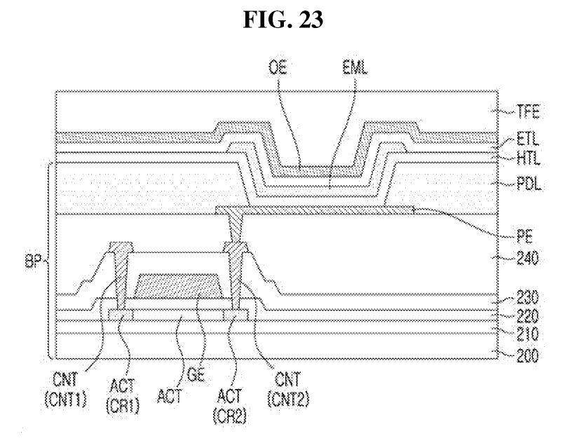

Thereafter, as shown in FIGS. 21 and 22, a light emitting layer EML (see FIG. 23) may be formed above the pixel electrode PE through a deposition process using the deposition mask M. Part (A) of FIG. 22 is a cross-sectional view schematically illustrating a deposition process, and part (B) is a plan view illustrating a state in which the light emitting layer EML is formed.

In one aspect, detailed illustrations of the components of the backplane structure BP, except for the base substrate 200, might not be shown in FIGS. 21 and 22 for ease of description.

Referring to FIGS. 21 and 22, a light emitting material included in the light emitting layer EML may be deposited from the deposition source DS using the deposition mask M. Accordingly, the light emitting layer EML may be formed on each of the pixel electrodes PE corresponding to the pixels. In some embodiments, deposition conditions such as substrate temperature, deposition rate, and chamber pressure may be controlled.

According to some embodiments, an organic light emitting material corresponding to the light emitting material may be supplied from the deposition source DS through thermal evaporation deposition. For example, the organic light emitting material may include a host material excited by holes and electrons, and a dopant material that increases light emission efficiency through absorption and emission of energy.

The organic light emitting material may be evaporated, injected into the deposition space S of the deposition mask M, and then discharged from the deposition hole DH onto the pixel electrode PE.

As shown in part (B) of FIG. 22, a plurality of light emitting layers EML may be formed in the second direction to form a column of light emitting layers. A plurality of the light emitting layer columns may be formed along the first direction. The arrangement may correspond to a matrix of sub-pixels in a display panel, with each column or row aligned to a color pattern sequence such as RGB or RGBW.

According to some embodiments, the formation of a first light emitting layer EML1 using a first light emitting material that emits a first color, a second light emitting layer EML2 using a second light emitting material that emits a second color, and a third light emitting layer EML3 using a third light emitting material that emits a third color may be sequentially performed while shifting the deposition mask M. The first to third colors may be different from each other. In some embodiments, the light emitting layer EML may correspond to a blue, red, or green light emitting layer. For example, the first color may be a red color, the second color may be a green color, and the third color may be a blue color. In some embodiments, an additional white light emitting layer may be formed to improve brightness or to enable RGBW pixel structures.

Referring to FIG. 23, an electron transport layer ETL may be formed on the pixel defining film PDL (or the hole transport layer HTL) and the light emitting layer EML formed as described with reference to FIG. 21. In some embodiments, the electron transport layer ETL may be formed as a common layer continuously provided across first to fourth pixels. In some cases, the electron transport layer ETL may cover the hole transport layer HTL and the light emitting layer EML.

The electron transport layer ETL may include an electron transport material such as an anthracene-based compound, tris(8-hydroxyquinolinato)aluminum (Alq₃), 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-Biphenylyl)-4-phenyl-5-tert-butylphenyl-1,2,4-triazole (TAZ), 4-(Naphthalen-1-yl)-3,5-diphenyl-4H-1,2,4-triazole (NTAZ), 2-(4-Biphenylyl)-5-(4-tert-butylphenyl)-1,3,4-oxadiazole (tBu-PBD), bis(2-methyl-8-quinolinolato-N1,O8)-(1,1'-Biphenyl-4-olato)aluminum (BAlq), and the like.

The electron transport layer ETL may be formed through a process such as thermal deposition, vapor deposition, vacuum deposition, spin coating, inkjet printing, laser printing, casting, or laser thermal transfer.

A counter electrode OE may be formed above the pixel defining film PDL and the light emitting layer EML. For example, the counter electrode OE may cover the entire upper surface of the electron transport layer ETL. The counter electrode OE may be formed on the electron transport layer ETL. In some embodiments, an electron injection layer may be formed between the counter electrode OE and the electron transport layer ETL.

The counter electrode OE may be formed as a common electrode commonly and continuously provided across the first to fourth pixels.

The counter electrode OE may be provided as an electron injection electrode or a cathode. The counter electrode OE may include a metal, alloy, or electrically conductive compound having a low work function.

For example, the counter electrode OE may include lithium (Li), silver (Ag), magnesium (Mg), aluminum (Al), aluminum-lithium (Al-Li), calcium (Ca), magnesium-indium (Mg-In), magnesium-silver (Mg-Ag), ytterbium (Yb), silver-ytterbium (Ag-Yb), ITO, IZO, or the like. These materials may be used alone or in combination with two or more.

The counter electrode OE may be formed as a transmissive electrode, a semi-transmissive electrode, or a reflective electrode. The counter electrode OE may have a single-layer structure or a multilayer structure.

An encapsulation layer TFE may be formed on the counter electrode OE. The encapsulation layer TFE may protect the light emitting layers EML from moisture or oxygen.

The encapsulation layer TFE may include: an inorganic film including silicon nitride (SiNx), silicon oxide (SiOx), indium tin oxide, indium zinc oxide, or any combination thereof; an organic film including polyethylene terephthalate, polyethylene naphthalate, polycarbonate, polyimide, polyethylene sulfonate, polyoxymethylene, polyarylate, hexamethyldisiloxane, acrylic resin (e.g., polymethyl methacrylate, polyacrylic acid, and the like), epoxy resin (e.g., aliphatic glycidyl ether (AGE), and the like), or a combination thereof; or a combination of the inorganic film and the organic film.

The encapsulation layer TFE may be formed in a single-layer structure or a multilayer structure. In some embodiments, the encapsulation layer TFE may have a sequentially stacked structure of a first inorganic layer, an organic layer, and a second inorganic layer.

In some embodiments, an optical functional layer or a sensor functional layer, such as a color filter, a polarizing plate, or a touch sensor layer, may additionally be formed on the encapsulation layer TFE.

By using the deposition mask M, the light emitting layers EML having a high resolution and a fine pitch may be formed. In some embodiments, the display device may be manufactured as an organic light emitting diode (OLED) display device having a high resolution of 500 ppi or more, or 1,000 ppi or more.

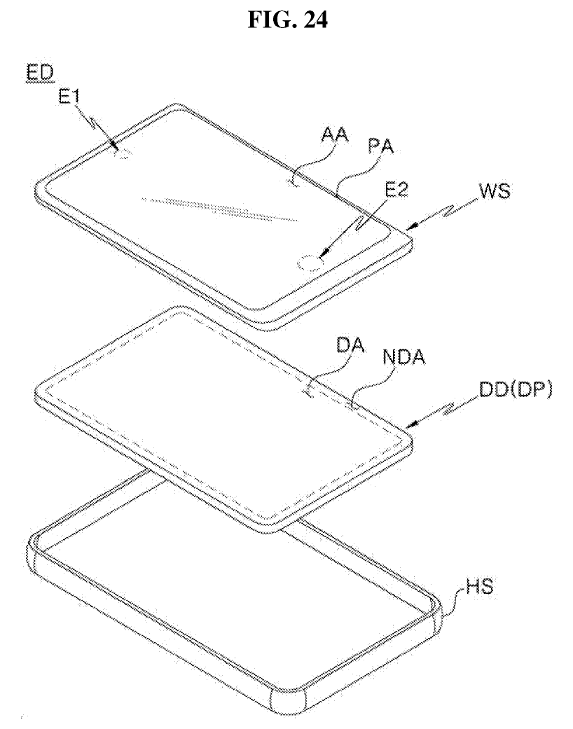

FIG. 24 is an exploded perspective view showing an electronic device according to embodiments of the present disclosure.

According to embodiments, an electronic device ED may be implemented in the form of a mobile phone (smartphone), a tablet, a PC, or other electronic devices, including a display device that includes a light emitting layer formed using the above-described deposition mask M.

Referring to FIG. 24, the electronic device ED may include a window structure WS, a display device DD, and a housing HS. The display device DD may include a display panel DP including a transistor and a light emitting element. With reference to FIG. 24, the housing HS, the display device DD, and the window structure WS may be sequentially stacked in a direction from bottom to top.

The window structure WS may provide an external display surface, such as the viewing surface of an electronic device such as a mobile phone, which is recognized by a user and may include a transparent material film. For example, the window structure WS may include glass (e.g., ultra-thin glass (UTG)), a hard-coated film, a plastic film, or the like.

The outer surface of the window structure WS may include an active area AA and a peripheral area PA surrounding the active area AA. The active area AA may provide a surface on which an image of the display device DD is substantially displayed and on which a touch/command from a user can be input. The peripheral area PA may substantially correspond to a bezel area of the electronic device ED. In some cases, functional circuits and signal lines may be disposed in the bezel area of the electronic device ED.

The display device DD or the display panel DP may include a display area DA and a non-display area NDA. The display area DA of the display panel DP may substantially correspond to or overlap the active area AA of the window structure WS. The non-display area NDA of the display panel DP may substantially correspond to or overlap the peripheral area PA of the window structure WS. In some cases, the non-display area NDA may completely or partially surround the display area DA.

In some embodiments, functional element regions E1 and E2 may be included in the active area AA of the window structure WS. For example, a first functional element region E1 may be included in one end portion of the active area AA and may be implemented in the form of a camera hole. A second functional element region E2 may be provided as a fingerprint sensing region. However, embodiments are not necessarily limited thereto. For example, the functional element regions may be implemented in the active area AA or the peripheral area PA.

For example, a sensor structure for touch sensing or fingerprint sensing may be located in the display panel DP or between the window structure WS and the display panel DP.

The housing HS may be provided as a support frame or a rear housing of the display device DD or the electronic device ED. A cover panel may be located between the housing HS and the display panel DP. The housing HS or the cover panel may include a plate (e.g., an SUS plate) that supports the display panel DP. The housing HS or the cover panel may also include an elastic body for absorbing impact on the display device DD.

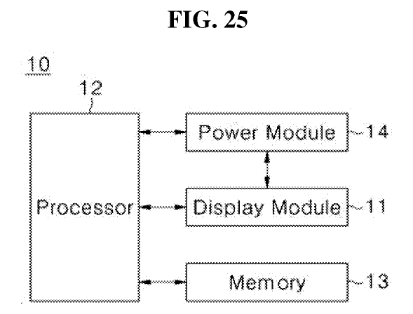

FIG. 25 is a block diagram of an electronic device according to an embodiment of the present disclosure.

Referring to FIG. 25, an electronic device 10 may include a display module 11, a processor 12, a memory 13, and a power module 14. In one aspect, electronic device 10 may be an example of, or includes aspects of, the electronic device ED described with reference to FIG. 24.

The processor 12 may include a central processing unit (CPU), an application processor (AP), a graphic processing unit (GPU), a communication processor (CP), an image signal processor (ISP), and/or a controller. In some cases, the processor 12 may control the overall operation of the electronic device 10, including driving the display module 11 based on image and data signals stored in memory 13. The power module 14 may supply and control electrical power provided to each of the functional components.

The memory 13 may store data information required for the operation of the processor 12 or the display module 11. When the processor 12 executes an application stored in the memory 13, an image data signal and/or an input control signal is transmitted to the display module 11, and the display module 11 may process the received signal and output image information through a display screen.

The power module 14 may include a power supply module, such as a power adapter or a battery device, and a power conversion module that converts power to operate the electronic device 10.

At least one of the components of the electronic device 10 described above may be included in the display device . Further, some of individual modules functionally included in one module may be included in the display device and some other modules may be provided separately from the display device. For example, the display module 11 includes a display device, and the processor 12, the memory 13, and the power module 14 may be provided in the form of other devices in the electronic device 10 other than the display device.

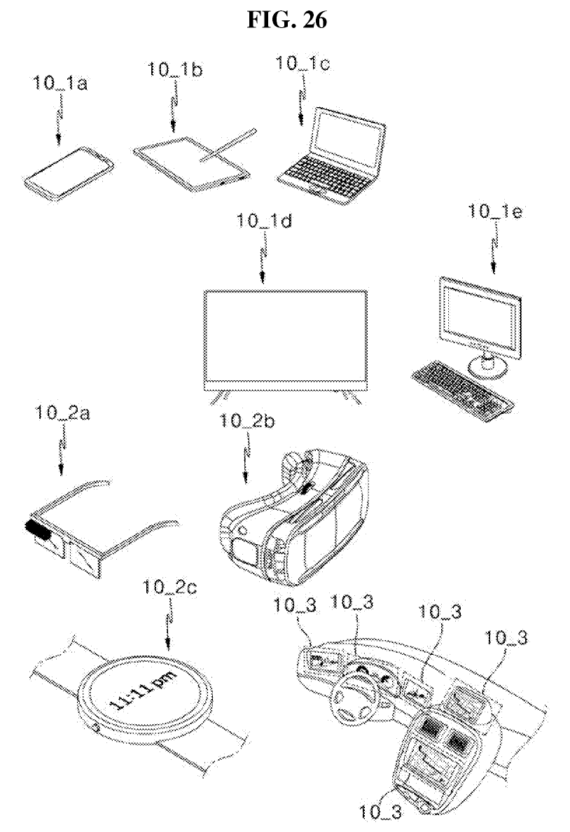

FIG. 26 is schematic views of electronic devices according to embodiments of the present disclosure.

Referring to FIG. 26, non-limiting examples of various electronic devices to which the display device is applied may include an image display electronic device such as a smartphone 10_1a, a tablet computer 10_1b, a laptop 10_1c, a television (TV) 10_1d, and a desktop monitor 10_1e; a wearable electronic device including a display module, such as smart glasses 10_2a, a head mounted display 10_2b, or a smart watch 10_2c; a vehicle electronic device 10_3 including a display module, such as a center fascia, and a dashboard of an automobile, a center information display (CID) placed on the dashboard, a room mirror display, and the like. The electronic device may include virtual reality glasses or augmented reality glasses.

The disclosure should not be construed as being limited to the embodiments set forth herein. Rather, these embodiments are provided so that this disclosure is thorough and complete and fully conveys the concept of the disclosure to those skilled in the art.

While the disclosure has been particularly shown and described with reference to embodiments thereof, it will be understood by those of ordinary skill in the art that various changes in form and details may be made therein without departing from the spirit or scope of the disclosure.

What is claimed is:

1. A method for manufacturing a deposition mask, comprising:
forming a first mask film and a second mask film on a first surface and a second surface of a mask body, respectively, wherein the first surface is opposite to the second surface;
etching the first mask film to form a mask pattern including deposition holes;
forming a protective oxide film on the mask pattern; and
etching the second mask film and the mask body to form a deposition space, wherein the deposition space is in common communication with the deposition holes.

2. The method of claim 1, wherein forming the deposition space comprises:
selectively removing a portion of the protective oxide film overlapping the deposition space.

3. The method of claim 1, wherein:
the first mask film comprises a silicon nitride, and
the protective oxide film comprises a silicon oxide.

4. The method of claim 1, wherein:
the protective oxide film is continuously formed along upper surfaces of the mask pattern, and side surfaces and bottom surfaces of the deposition holes through a deposition process.

5. The method of claim 1, wherein:
the protective oxide film is formed to partially fill each of the deposition holes through an oxidation process on the mask body or the mask pattern.

6. The method of claim 5, further comprising:
partially etching an upper portion of the mask body using the mask pattern to form recesses.

7. The method of claim 6, wherein:
the protective oxide film completely fills the recesses and is in contact with side surfaces of the mask pattern.

8. The method of claim 7, wherein:
the protective oxide film includes a first portion disposed on a top surface of the mask pattern, and a second portion formed in the deposition holes.

9. The method of claim 1, further comprising:
forming a guide structure including a magnetic material or a conductive material on the second mask film opposite from the mask body,
wherein the deposition space penetrates the guide structure.

10. The method of claim 9, further comprising:
forming a seed pattern on the second mask film opposite from the mask body,
wherein the guide structure is formed through a plating process using the seed pattern.

11. The method of claim 1, further comprising:
forming a buffer oxide film on the first surface or the second surface of the mask body.

12. A deposition mask, comprising:
a mask body having a first surface and a second surface opposite from the first surface, and including a deposition space;
a mask pattern located on the first surface of the mask body, wherein the mask pattern includes a plurality of deposition holes communicating with the deposition space in a pattern region; and
a protective oxide film pattern formed on an outer region of the mask pattern, wherein the outer region surrounds the pattern region.

13. The deposition mask of claim 12, further comprising:
a second mask film formed on the second surface of the mask body,
wherein the deposition space penetrates the second mask film and the mask body.

14. The deposition mask of claim 13, further comprising:
a guide structure spaced apart from the mask body with the second mask film interposed between the guide structure and the mask body, wherein the guide structure includes a magnetic material or a conductive material and surrounding a bottom portion of the deposition space.

15. The deposition mask of claim 14, further comprising:
a seed pattern disposed between the guide structure and the second mask film.

16. The deposition mask of claim 13, wherein:
the mask pattern and the second mask film comprise a silicon nitride.

17. The deposition mask of claim 12, wherein:
the deposition space is configured to receive a deposition material, and the plurality of deposition holes are configured to discharge the deposition material.

18. A method of manufacturing a display device, comprising:
preparing a display panel comprising pixel electrodes; and
forming light emitting layers by depositing a light emitting material on the pixel electrodes through a deposition mask,
wherein the deposition mask comprises:
a mask body having a first surface and a second surface opposite from the first surface, and including a deposition space;
a mask pattern located on the first surface of the mask body, wherein the mask pattern includes a plurality of deposition holes communicating with the deposition space in a pattern region; and
a protective oxide film pattern formed on an outer region of the mask pattern, wherein the outer region surrounds the pattern region.

19. The method of claim 18, wherein the deposition mask further comprises:
a guide structure disposed on the second surface of the mask body, wherein the guide structure includes a magnetic material or a conductive material and surrounding a bottom portion of the deposition space.

20. The method of claim 18, wherein:
the deposition space is configured to receive a deposition material, and the plurality of deposition holes are configured to discharge the deposition material.
